(19) United States
(12) Patent Application Publication
(10) Pub. No.: US 2023/0066996 A1
(43) Pub. Date: Mar. 2, 2023

(54) LATERAL BIPOLAR JUNCTION TRANSISTORS CONTAINING A TWO-DIMENSIONAL MATERIAL

(71) Applicant: GlobalFoundries U.S. Inc., Malta, NY (US)

(72) Inventors: Arkadiusz Malinowski, Dresden (DE); Alexander Derrickson, Saratoga Springs, NY (US)

(21) Appl. No.: 17/541,603

(22) Filed: Dec. 3, 2021

Related U.S. Application Data
(60) Provisional application No. 63/239,663, filed on Sep. 1, 2021.

(51) Int. Cl. H01L 29/735; H01L 29/24; H01L 21/02; H01L 29/66

(52) U.S. Cl. CPC H01L 29/735; H01L 21/02568; H01L 29/24; H01L 29/66969

(57) ABSTRACT

Structures for a bipolar junction transistor and methods of fabricating a structure for a bipolar junction transistor. The structure includes an emitter and a collector comprised of a first two-dimensional material having a first conductivity type, and an intrinsic base comprised of a second two-dimensional material having a second conductivity type different than the first conductivity type. The intrinsic base is laterally positioned between the emitter and the collector.

### CROSS-REFERENCE TO RELATED APPLICATIONS

This application claims the benefit of U.S. Provisional Application No. 63/239,663, filed Sep. 1, 2021, which is hereby incorporated by reference herein in its entirety.

### BACKGROUND

The disclosure relates generally to semiconductor devices and integrated circuit fabrication and, in particular, to structures for a bipolar junction transistor and methods of forming a structure for a bipolar junction transistor.

A bipolar junction transistor is a multi-terminal electronic device that includes an emitter, a collector, and an intrinsic base arranged between the emitter and collector. In an NPN bipolar junction transistor, the emitter and collector are composed of n-type semiconductor material, and the intrinsic base is composed of p-type semiconductor material. In a PNP bipolar junction transistor, the emitter and collector are composed of p-type semiconductor material, and the intrinsic base is composed of n-type semiconductor material. During operation, the base-emitter junction is forward biased, the base-collector junction is reverse biased, and the collector-emitter current may be controlled with the base-emitter voltage.

A heterojunction bipolar transistor is a variant of a bipolar junction transistor in which the semiconductor materials of the terminals have different energy bandgaps, which creates heterojunctions. For example, the collector and/or emitter of a heterojunction bipolar transistor may be constituted by silicon, and the intrinsic base of a heterojunction bipolar transistor may be constituted by a silicon-germanium alloy, which is characterized by a narrower band gap than silicon.

Improved structures for a bipolar junction transistor and methods of fabricating a structure for a bipolar junction transistor are needed.

### SUMMARY

In an embodiment, a structure for a bipolar junction transistor is provided. The structure includes an emitter and a collector comprised of a first two-dimensional material having a first conductivity type, and an intrinsic base comprised of a second two-dimensional material having a second conductivity type different than the first conductivity type. The intrinsic base is laterally positioned between the emitter and the collector.

In an embodiment, a method of fabricating a structure for a bipolar junction transistor is provided. The method includes forming an emitter and a collector comprised of a first two-dimensional material having a first conductivity type, and forming an intrinsic base comprised of a second two-dimensional material having a second conductivity type different than the first conductivity type. The intrinsic base is laterally positioned between the emitter and the collector.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-5 are cross-sectional views of a structure for a lateral bipolar junction transistor at successive fabrication stages of a processing method in accordance with embodiments of the invention.

### DETAILED DESCRIPTION

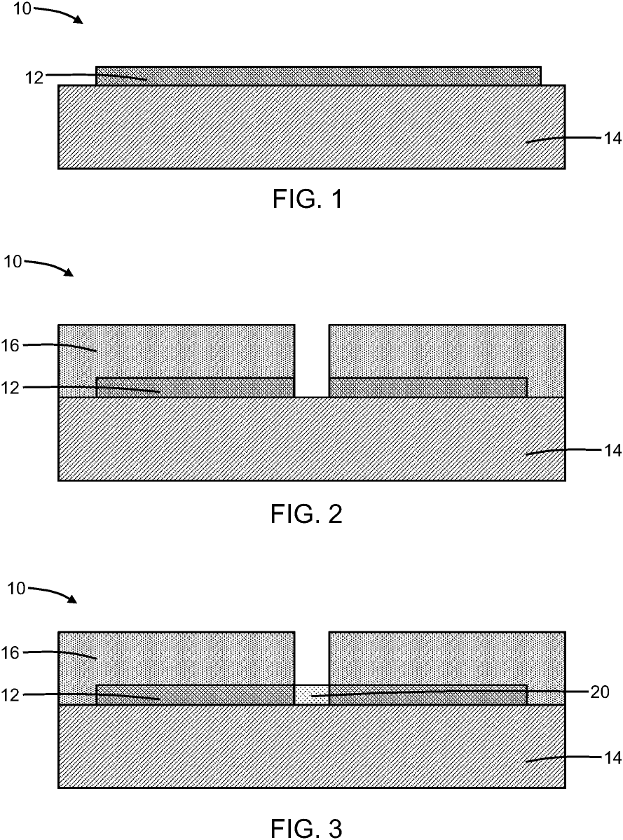

With reference to FIG. 1 and in accordance with embodiments of the invention, a structure 10 for a lateral bipolar junction transistor includes a layer 12 containing a two-dimensional (2D) material. The layer 12 may be deposited on a substrate 14 (e.g., a dielectric layer) by, for example, metal organic chemical vapor deposition, and then patterned with lithography and etching processes. The patterned layer 12 may be embodied in a thin sheet that is arranged in a horizontal plane that is parallel to a horizontal plane of the surface of the substrate 14. The patterned layer 12 has a set of major dimensions (e.g., length and width) that may be significantly greater than the thickness of the layer 12. In an embodiment, the layer 12 may include a single monolayer of atoms of the two-dimensional material that are arranged in the thin sheet. In an embodiment, the thin sheet constituting the layer 12 may include one monolayer of atoms to three monolayers of atoms of the two-dimensional material. In an embodiment, the thickness of the layer 12 may be less than 10 nanometers.

In an embodiment, the two-dimensional material of the layer 12 may be comprised of a transition metal dichalcogenide that is comprised of a transition metal (e.g., molybdenum or tungsten) and a chalcogen (e.g., sulfur, selenium, or tellurium). Exemplary transition metal dichalcogenides include, but are not limited to, tungsten disulfide, molybdenum disulfide, hafnium disulfide, zirconium disulfide, tin sulfide, and tungsten diselenide. In an embodiment, the two-dimensional material of the layer 12 may be comprised of tungsten disulfide.

The two-dimensional material of the layer 12 may be doped for example, during deposition. In an alternative embodiment, the two-dimensional material of the layer 12 may be doped following its deposition by a non-destructive process, such as by a plasma doping process. In an embodiment, the two-dimensional material of the layer 12 may be doped to have n-type conductivity. In an embodiment, the two-dimensional material of the layer 12 may be comprised of a transition metal dichalcogenide doped with atoms of tin to provide n-type conductivity. In an embodiment, the two-dimensional material of the layer 12 may be comprised of tungsten disulfide doped with atoms of tin to provide n-type conductivity. In an alternative embodiment, the two-dimensional material of the layer 12 may be doped to have p-type conductivity.

With reference to FIG. 2 in which like reference numerals refer to like features in FIG. 1 and at a subsequent fabrication stage, a hardmask 16 is formed over the layer 12. The hardmask 16 may include a pad layer comprised of a dielectric material, such as silicon nitride, and may be patterned by lithography and etching processes to define an opening that exposes a surface area of the layer 12. In that regard, the hardmask 16 may be patterned using an etch mask formed by lithography. The etch mask may include a layer of photoresist applied by a spin-coating process, pre-baked, exposed to light projected through a photomask, baked after exposure, and developed with a chemical developer to define the opening to be formed in the hardmask 16. An etching process, such as a reactive ion etching process, may then be used to remove portions of the pad layer exposed by the opening in the etch mask, which is subsequently stripped, to define the opening in the hardmask 16.

The portion of the layer 12 exposed by the opening in the hardmask 16 may be removed by an etching process. Layer sections of the layer 12 covered by the hardmask 16 are preserved during the etching process. In an embodiment, the portion of the layer 12 exposed by the opening in the hardmask 16 may be fully removed by the etching process such that the substrate 14 is exposed. The etching process may be a soft-landing etching process in which the substrate 14 is not damaged during the removal of the portion of the layer 12. The opening in the layer 12 is positioned between, and separates, the layer sections of the layer 12.

With reference to FIG. 3 in which like reference numerals refer to like features in FIG. 2 and at a subsequent fabrication stage, a layer 20 may be deposited on the area of the substrate 14 exposed by the removal of layer 12. The layer 20 may be deposited by, for example, metal organic chemical vapor deposition. In an embodiment, the layer 20 may be deposited by selective metal organic chemical vapor deposition. In an embodiment, the layer 20 may have a thickness that is equal or substantially equal to the thickness of the layer 12.

The layer 20 contains a two-dimensional material that may be doped, for example, during deposition to have a conductivity type of opposite polarity to the conductivity type of the layer 12. In an alternative embodiment, the two-dimensional material of the layer 20 may be doped following its deposition by a non-destructive process, such as by a plasma doping process. In an embodiment, the layer 20 may contain a two-dimensional material that is doped to have p-type conductivity. In an embodiment, the two-dimensional material of the layer 20 may be comprised of a transition metal dichalcogenide that includes a transition metal (e.g., molybdenum or tungsten) and a chalcogen (e.g., sulfur, selenium, or tellurium). Exemplary transition metal dichalcogenides include, but are not limited to, tungsten disulfide, molybdenum disulfide, hafnium disulfide, zirconium disulfide, tin sulfide, and tungsten diselenide. In an embodiment, the two-dimensional material of the layer 20 may be comprised of a transition metal dichalcogenide that is doped to have p-type conductivity. In an embodiment, the two-dimensional material of the layer 20 may be comprised of tungsten disulfide that is doped with atoms of vanadium to provide p-type conductivity. In an alternative embodiment, the two-dimensional material of the layer 20 may be doped to have n-type conductivity.

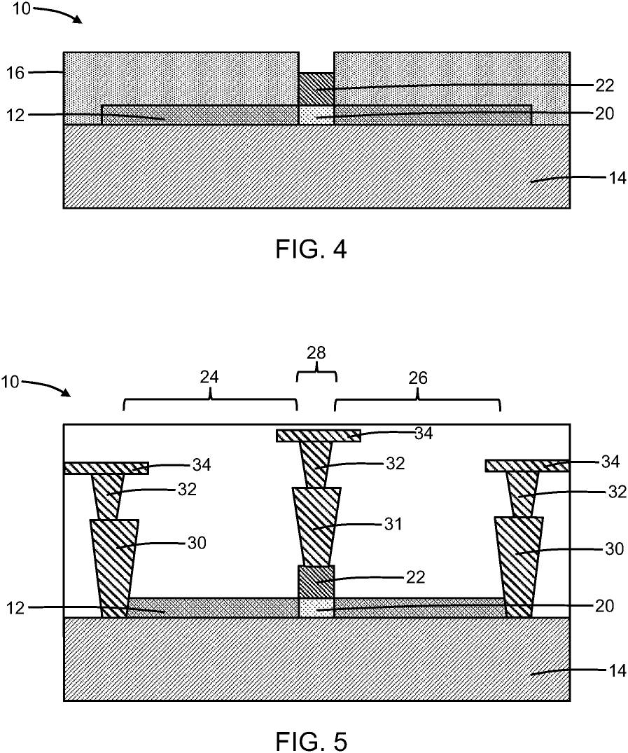

With reference to FIG. 4 in which like reference numerals refer to like features in FIG. 3 and at a subsequent fabrication stage, a layer 22 may be deposited on the layer 20 by, for example, metal organic chemical vapor deposition. In an embodiment, the layer 22 may be deposited by selective metal organic chemical vapor deposition. The layer 22 is stacked above the layer 20 inside the opening in the hardmask 16.

The layer 22 contains a two-dimensional material that may be doped, for example, during deposition to have a conductivity type of the same polarity as the conductivity type of the layer 20. In an alternative embodiment, the two-dimensional material of the layer 22 may be doped following its deposition by a non-destructive process, such as by a plasma doping process. In an embodiment, the layer 22 may contain a two-dimensional material that is doped to have p-type conductivity. In an embodiment, the layer 22 may have a dopant concentration that is greater than the dopant concentration of the layer 20. In an embodiment, the two-dimensional material of the layer 22 may be comprised of a transition metal dichalcogenide that includes a transition metal (e.g., molybdenum or tungsten) and a chalcogen (e.g., sulfur, selenium, or tellurium). Exemplary transition metal dichalcogenides include, but are not limited to, tungsten disulfide, molybdenum disulfide, hafnium disulfide, zirconium disulfide, tin sulfide, and tungsten diselenide. In an embodiment, the two-dimensional material of the layer 22 may be comprised of a transition metal dichalcogenide that is doped to have p-type conductivity. In an embodiment, the two-dimensional material of the layer 22 may be comprised of tungsten disulfide that is doped with vanadium to provide p-type conductivity. In an alternative embodiment, the two-dimensional material of the layer 22 may be doped to have n-type conductivity.

With reference to FIG. 5 in which like reference numerals refer to like features in FIG. 4 and at a subsequent fabrication stage, the hardmask 16 is stripped such that the sections of the layer 12 are re-exposed. Specifically, the stacked layers 20, 22 are positioned in a lateral direction between different layer sections of the layer 12. In an embodiment, the stacked layers 20, 22 may collectively have a greater thickness than the layer 12. The layer 22 is positioned in a vertical direction (i.e., in elevation) fully above a top surface 13 of the layer 12.

The different layer sections of the layer 12 define terminals of the lateral bipolar junction transistor, namely a collector 24 and an emitter 26. The layers 20, 22 provide contributions defining a base 28 of the lateral bipolar junction transistor. Specifically, the layer 20 defines an intrinsic base of the base 28 of the lateral bipolar junction transistor, and the layer 22 defines an extrinsic base of the base 28 of the lateral bipolar junction transistor. The base 28 is laterally (i.e., horizontally) positioned in a horizontal plane adjacent to the layer section of the layer 12 defining the collector 24 and the layer section of the layer 12 defining the emitter 26. In an embodiment, the layers 20, 22 of the base 28 may be centrally positioned in a horizontal direction between the different layer sections of the layer 12 defining the collector 24 and emitter 26. The two-dimensional material of the collector 24 and emitter 26 have an opposite conductivity type from the two-dimensional material of the base 28. In an embodiment, the two-dimensional material of the collector 24 and emitter 26 may be doped to have n-type conductivity and the two-dimensional material of the base 28 may be doped to have p-type conductivity to provide an NPN lateral bipolar junction transistor. In an alternative embodiment, the two-dimensional material of the collector 24 and emitter 26 may be doped to have p-type conductivity and the two-dimensional material of the base 28 may be doped to have n-type conductivity to provide a PNP lateral bipolar junction transistor.

Middle-of-line (MOL) processing and back-end-of-line (BEOL) processing follow, which includes the formation of contacts 30 coupled to the collector 24 and emitter 26, and a contact 31 coupled to the layer 22 of the base 28, as well as the formation of an interconnect structure that includes vias 32 and wires 34 that are coupled by the contacts 30, 31 to the collector 24, emitter 26, and base 28 of the lateral bipolar junction transistor. The etching process used to form the contact opening for the contact 31 may be a soft-landing etching process in which the layer 22 of the base 28 is not damaged. The contacts 30, 31, vias 32, and wires 34 may be formed by damascene processes in one or more dielectric layers 36. The contacts 30 may be physically and electrically connected to the collector 24 and emitter 26 at opposite side edges of the layer 12, and the contact 31 may be physically and electrically connected to the base 28.

The collector 24, emitter 26, and base 28 of the bipolar junction transistor have a lateral arrangement with horizontal relative positioning. The collector 24, emitter 26, and base 28 include two-dimensional materials characterized by horizontally-adjacent regions of different conductivity type. The collector 24 and emitter 26 are regions of the same conductivity type, and the base 28 is a region having an opposite conductivity type from regions of the collector 24 and emitter 26. The two-dimensional materials of the collector 24, emitter 26, and base 28 may provide a performance enhancement for the lateral bipolar junction transistor due to having a higher carrier mobility than a silicon-based material.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value specified. The language of approximation may correspond to the precision of an instrument used to measure the value and, unless otherwise dependent on the precision of the instrument, may indicate +/- 10% of the stated value(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction perpendicular to the horizontal, as just defined. The term “lateral” refers to a direction within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. Different features “overlap” if a feature extends over, and covers a part of, another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure for a lateral bipolar junction transistor, the structure comprising:
an emitter comprised of a first two-dimensional material having a first conductivity type;
a collector comprised of the first two-dimensional material; and
an intrinsic base comprised of a second two-dimensional material having a second conductivity type different than the first conductivity type, the intrinsic base laterally positioned between the emitter and the collector.

2. The structure of claim 1 wherein the first two-dimensional material is a first transition metal dichalcogenide.

3. The structure of claim 2 wherein the second two-dimensional material is a second transition metal dichalcogenide.

4. The structure of claim 3 wherein the first transition metal dichalcogenide includes an n-type dopant, and the second transition metal dichalcogenide includes a p-type dopant.

5. The structure of claim 3 wherein the first transition metal dichalcogenide is tungsten disulfide including an n-type dopant, and the second transition metal dichalcogenide is tungsten disulfide including a p-type dopant.

6. The structure of claim 1 further comprising:
an extrinsic base arranged in a layer stack with the intrinsic base, the extrinsic base comprised of a third two-dimensional material.

7. The structure of claim 6 wherein the third two-dimensional material has the second conductivity type.

8. The structure of claim 6 wherein the second two-dimensional material and the third two-dimensional material include a dopant, and the third two-dimensional material contains a greater concentration of the dopant than the second two-dimensional material.

9. The structure of claim 6 wherein the second two-dimensional material and the third two-dimensional material each comprise a transition metal dichalcogenide.

10. The structure of claim 1 wherein the intrinsic base, the emitter, and the collector have substantially-equal thicknesses.

11. The structure of claim 1 wherein the emitter and the collector are respective layer sections of a layer containing the first two-dimensional material.

12. The structure of claim 1 further comprising:
a substrate,
wherein the emitter, the intrinsic base, and the collector are arranged in a horizontal plane over the substrate.

13. The structure of claim 12 further comprising:
an extrinsic base arranged in a layer stack with the intrinsic base, the extrinsic base comprised of a third two-dimensional material, and the intrinsic base positioned in a vertical direction between the extrinsic base and the substrate.

14. A method of fabricating a structure for a lateral bipolar transistor, the method comprising:
forming an emitter and a collector comprised of a first two-dimensional material having a first conductivity type; and
forming an intrinsic base comprised of a second two-dimensional material having a second conductivity type different than the first conductivity type, wherein the intrinsic base is laterally positioned between the emitter and the collector.

15. The method of claim 14 wherein forming the emitter and the collector comprised of the first two-dimensional material comprises:
depositing a first layer of the first two-dimensional material; and
patterning the first layer to define a first layer section defining the emitter and a second layer section defining the collector.

16. The method of claim 15 wherein forming the intrinsic base comprised of the second two-dimensional material having the second conductivity type different than the first conductivity type comprises:
depositing a second layer in an opening between the first layer section and the second layer section.

17. The method of claim 16 further comprising:
depositing a third layer on the second layer,
wherein the third layer is comprised of a third two-dimensional material.

18. The structure of claim 17 wherein the third two-dimensional material has the second conductivity type, the second two-dimensional material and the third two-dimensional material include a dopant, and the third two-dimensional material contains a greater concentration of the dopant than the second two-dimensional material.

19. The method of claim 15 wherein the first two-dimensional material is a first transition metal dichalcogenide, and the second two-dimensional material is a second transition metal dichalcogenide.

20. The method of claim 15 wherein the intrinsic base, the emitter, and the collector have substantially-equal thicknesses.
